(19) United States
(12) Patent Application Publication
(10) Pub. No.: US 2025/0151267 A1
(43) Pub. Date: May 8, 2025

(54) SEMICONDUCTOR MEMORY DEVICE

(71) Applicant: Socionext Inc., Kanagawa (JP)

(72) Inventor: Yasumitsu SAKAI, Yokohama-shi, Kanagawa (JP)

(21) Appl. No.: 19/015,181

(22) Filed: Jan. 9, 2025

Related U.S. Application Data
(63) Continuation of application No. PCT/JP2023/024405, filed on Jun. 30, 2023.

(30) Foreign Application Priority Data
Jul. 21, 2022 (JP) 2022-116479

(51) Int. Cl. H10B 20/00

(52) U.S. Cl. CPC H10B 20/34

(57) ABSTRACT

A ROM cell using a complementary FET (CFET) includes: a first three-dimensional transistor provided between a first bit line and a first ground power supply line, and a second three-dimensional transistor provided between a second bit line and a second ground power supply line. Channel portions of the first and second transistors overlap each other in planar view. First data is stored depending on the presence or absence of connection between the source of the first transistor and the first ground power supply line. Second data is stored depending on the presence or absence of connection between the source of the second transistor and the second ground power supply line. The first and second bit lines are formed in a buried interconnect layer.

### CROSS-REFERENCE TO RELATED APPLICATIONS

This is a continuation of International Application No. PCT/JP2023/024405 filed on Jun. 30, 2023, which claims priority to Japanese Patent Application No. 2022-116479 filed on Jul. 21, 2022. The entire disclosures of these applications are incorporated by reference herein.

### BACKGROUND

The present disclosure relates to a semiconductor memory device, and more particularly to a layout structure of a mask read only memory (ROM).

A mask ROM includes memory cells arranged in an array, and each memory cell is programmed to have a fixed data state during manufacture. A transistor constituting the memory cell is provided between a bit line and VSS and connected to a word line at its gate. Bit data “1” or “0” is stored in the memory cell depending on the presence or absence of connection between its source or drain and the bit line or VSS. The presence or absence of connection is realized by the presence or absence of a contact or a via, for example.

Also, as for a transistor, which is a basic constituent of an LSI, improvement in integration degree, reduction in operating voltage, and improvement in operating speed have been achieved by reducing (scaling) the gate length. In recent years, however, increase in off current due to excessive scaling and the resulting significant increase in power consumption have raised a problem. To solve this problem, three-dimensional transistors, such as a fin field effect transistor (FET) and a nanosheet FET, of which the transistor structure has changed from the conventional planar structure to a three-dimensional structure, have been vigorously studied.

International Patent Publication No. WO 2020/230665 discloses a layout structure of a ROM cell using a complementary FET (CFET).

In the mask ROM described in the cited patent document, interconnects in an M1 interconnect layer located above transistors are used as bit lines. As semiconductor integrated circuits are being further miniaturized, however, the resistance values of interconnects are becoming larger, and this causes problems such as decrease in the operating speed of the mask ROM due to the resistance of the bit lines. If the line width of the bit lines is made large to reduce the resistance of the bit lines, a problem that the area of the mask ROM will increase will arise.

An objective of the present disclosure is providing a layout structure of a mask ROM using CFETs in which decrease in operating speed is prevented without increase in area.

### SUMMARY

According to the first mode of the present disclosure, a semiconductor memory device having a read only memory (ROM) cell, includes: a word line extending in a first direction; first and second bit lines extending in a second direction perpendicular to the first direction, formed in a buried interconnect layer; and first and second ground power supply lines extending in the second direction, wherein the ROM cell includes a first transistor that is a three-dimensional transistor provided between the first bit line and the first ground power supply line, and a second transistor that is a three-dimensional transistor provided between the second bit line and the second ground power supply line, formed above the first transistor, channel portions of the first and second transistors overlapping each other in planar view, gates of the first and second transistors are connected to the word line, and the ROM cell stores first data depending on the presence or absence of connection between a source of the first transistor and the first ground power supply line, or the presence or absence of connection between a drain of the first transistor and the first bit line, and stores second data depending on the presence or absence of connection between a source of the second transistor and the second ground power supply line, or the presence or absence of connection between a drain of the second transistor and the second bit line.

According to the above mode, a ROM cell includes: a first transistor that is a three-dimensional transistor provided between a first bit line and a first ground power supply line, and a second transistor that is a three-dimensional transistor provided between a second bit line and a second ground power supply line. The second transistor is formed above the first transistor, and channel portions of the first and second transistors overlap each other in planar view. The ROM cell stores first data depending on the presence or absence of connection between the source of the first transistor and the first ground power supply line, or the presence or absence of connection between the drain of the first transistor and the first bit line. Also, the ROM cell stores second data depending on the presence or absence of connection between the source of the second transistor and the second ground power supply line, or the presence or absence of connection between the drain of the second transistor and the second bit line. In this way, a small-area layout structure can be implemented for the mask ROM. In addition, since the first and second bit lines are formed in the buried interconnect layer, the resistance value of the first and second bit lines can be reduced by increasing the thickness thereof in the depth direction. It is therefore possible to prevent decrease in the operating speed of the mask ROM without increasing the area.

According to the second mode of the present disclosure, a semiconductor memory device having a read only memory (ROM) cell, includes: a word line extending in a first direction; a bit line extending in a second direction perpendicular to the first direction, formed in a buried interconnect layer; and a ground power supply line extending in the second direction, wherein the ROM cell includes a first transistor that is a three-dimensional transistor provided between the bit line and the ground power supply line, and a second transistor that is a three-dimensional transistor provided between the bit line and the ground power supply line, formed above the first transistor, channel portions of the first and second transistors overlapping each other in planar view, in the first and second transistors, gates are connected to the word line, sources are connected to each other, and drains are connected to each other, and the ROM cell stores data depending on the presence or absence of connection between the sources of the first and second transistors and the ground power supply line, or the presence or absence of connection between the drains of the first and second transistors and the bit line.

According to the above mode, a ROM cell includes first and second transistors that are three-dimensional transistors provided between a bit line and a ground power supply line. The second transistor is formed above the first transistor, and channel portions of the first and second transistors overlap each other in planar view. The sources of the first and second transistors are connected to each other, and the drains thereof are connected to each other. The ROM cell stores data depending on the presence or absence of connection between the sources of the first and second transistors and the ground power supply line, or the presence or absence of connection between the drains of the first and second transistors and the bit line. In this way, a small-area layout structure can be implemented for the mask ROM. In addition, since the bit line is formed in the buried interconnect layer, the resistance value of the bit line can be reduced by increasing the thickness thereof in the depth direction. It is therefore possible to prevent decrease in the operating speed of the mask ROM without increasing the area.

According to the present disclosure, a layout structure of a mask ROM using CFETs in which decrease in operating speed is prevented without increase in area can be provided.

### BRIEF DESCRIPTION OF THE DRAWINGS

FIG. 1 is a circuit diagram showing a configuration of a contact-type mask ROM as an example of the semiconductor memory device.

FIGS. 2A-2B are plan views showing a layout structure example of a memory cell according to the first embodiment.

FIGS. 3A-3C are cross-sectional views of the layout structure of FIGS. 2A-2B.

FIG. 4 shows a layout structure of an upper part of a memory cell array using the memory cell of FIGS. 2A-2B and 3A-3C.

FIG. 5 shows a layout structure of a lower part of the memory cell array using the memory cell of FIGS. 2A-2B and 3A-3C.

FIGS. 6A-6B are plan views showing another layout structure example of the memory cell according to the first embodiment.

FIGS. 7A-7B are plan views showing a layout structure example of a memory cell according to the second embodiment.

FIGS. 8A-8C are cross-sectional views of the layout structure of FIGS. 7A-7B.

FIG. 9 shows a layout structure of an upper part of a memory cell array using the memory cell of FIGS. 7A-7B and 8A-8C.

FIG. 10 shows a layout structure of a lower part of the memory cell array using the memory cell of FIGS. 7A-7B and 8A-8C.

FIG. 11 shows a layout example of a memory array unit of a semiconductor memory device according to the second embodiment.

FIGS. 12A-12B are plan views showing another layout structure example of the memory cell according to the second embodiment.

FIG. 13 shows another layout example of the memory array unit of the semiconductor memory device according to the second embodiment.

FIGS. 14A-14B are plan views showing a layout structure example of a memory cell according to the third embodiment.

FIG. 15 shows a layout structure of an upper part of a memory cell array using the memory cell of FIGS. 14A-14B.

FIG. 16 shows a layout structure of a lower part of the memory cell array using the memory cell of FIGS. 14A-14B.

### DETAILED DESCRIPTION

Embodiments of the present disclosure will be described hereinafter with reference to the accompanying drawings. As used herein, “VDD” and “VSS” refer to power supply voltages or power supplies themselves. Also, the source region and drain region of a transistor are herein called the “nodes” of the transistor as appropriate. That is, one node of a transistor refers to the source or drain of the transistor, and both nodes of a transistor refer to the source and drain of the transistor.

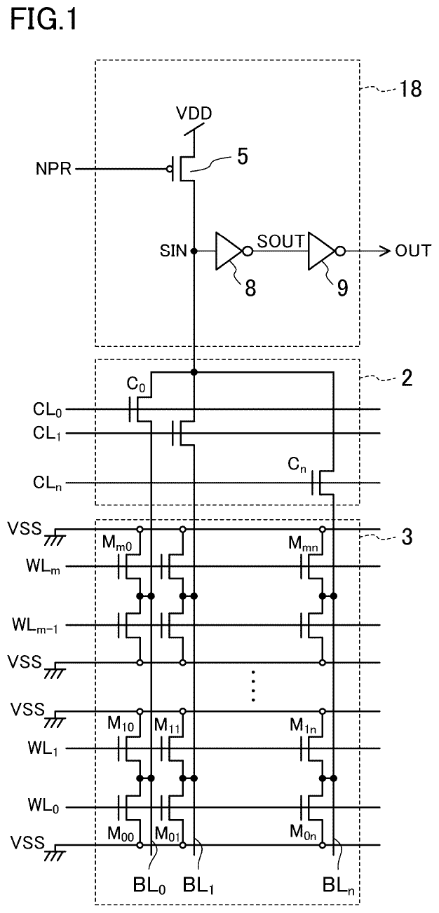

FIG. 1 is a circuit diagram showing a configuration of a contact-type mask ROM as an example of the semiconductor memory device. The mask ROM shown in FIG. 1 is a ROM in which whether or not the source of a memory cell transistor is connected to a ground line VSS through a contact is made to correspond to “0” or “1” of memory data.

In FIG. 1, the mask ROM includes a memory cell array 3, a column decoder 2, and a sense amplifier 18.

The memory cell array 3 is constituted by memory cells Mij (i=0 to m, j=0 to n) of n-type MOS transistors arranged in a matrix. The gates of the memory cells Mij are connected to corresponding word lines WLi that are common for each row, and the drains thereof are connected to corresponding bit lines BLj that are common for each column. The sources of the memory cells Mij are connected to the ground potential VSS when the memory data is intended to be “0”, and are not connected to the ground potential VSS when it is intended to be “1”.

The column decoder 2 is constituted by n-type MOS transistors Cj. The drains of the n-type MOS transistors Cj are all connected together as a common drain, the gates thereof are connected to corresponding column selection signal lines CLj, and the sources thereof are connected to the corresponding bit lines BLj.

The sense amplifier 18 includes a precharge p-type MOS transistor 5, an inverter 8 that judges the output data of the memory cells Mij, and an inverter 9 that buffers the output signal of the inverter 8. A precharge signal NPR is input into the gate of the p-type MOS transistor 5, the power supply voltage VDD is supplied to the source thereof, and the drain thereof is connected to the common drain of the n-type MOS transistors Cj. The inverter 8, receiving a signal SIN from the common drain of the n-type MOS transistors Cj, judges the output data of the memory cells Mij. The inverter 9, receiving an output signal SOUT of the inverter 8, outputs memory data of the memory cells Mij.

The operation of the mask ROM of FIG. 1 will be described taking as an example the case of reading data of the memory cell M00.

First, among the column selection signal lines CLj, CL0 is made high and the other CL1 to CLn are made low. This turns on the transistor C0, among the transistors constituting the column decoder 2, and turns off the other transistors C1 to Cn. Also, a word line WL0 is changed from a low level as the non-selected state to a high level as the selected state.

The precharge signal NPR is then changed from high to low, to turn on the precharge p-type MOS transistor 5.

In the case where the source of the memory cell M00 is connected to the ground potential VSS, since the current capability of the memory cell M00 is greater than that of the precharge p-type MOS transistor 5, the input signal SIN of the inverter 8 becomes lower in voltage than the switching level of the inverter 8. Therefore, the output signal SOUT of the inverter 8 keeps high, and an output signal OUT of the inverter 9 keeps low.

On the other hand, in the case where the source of the memory cell M00 is not connected to the ground potential VSS, the bit line BL0 is charged by the precharge p-type MOS transistor 5, and thus the input signal SIN of the inverter 8 becomes higher in voltage than the switching level of the inverter 8. Therefore, the output signal SOUT of the inverter 8 becomes low, and the output signal OUT of the inverter 9 becomes high.

That is, when the source of a memory cell is connected to VSS, a low level is output (memory data “0”), and when the source of a memory cell is not connected to VSS, a high level is output (memory data “1”).

Note that, in the mask ROM according to this disclosure, as the method of storing a value in each memory cell, there are a case of setting the value by connection or disconnection between the memory cell and VSS and a case of setting the value by connection or disconnection between the memory cell and a bit line.

### First Embodiment

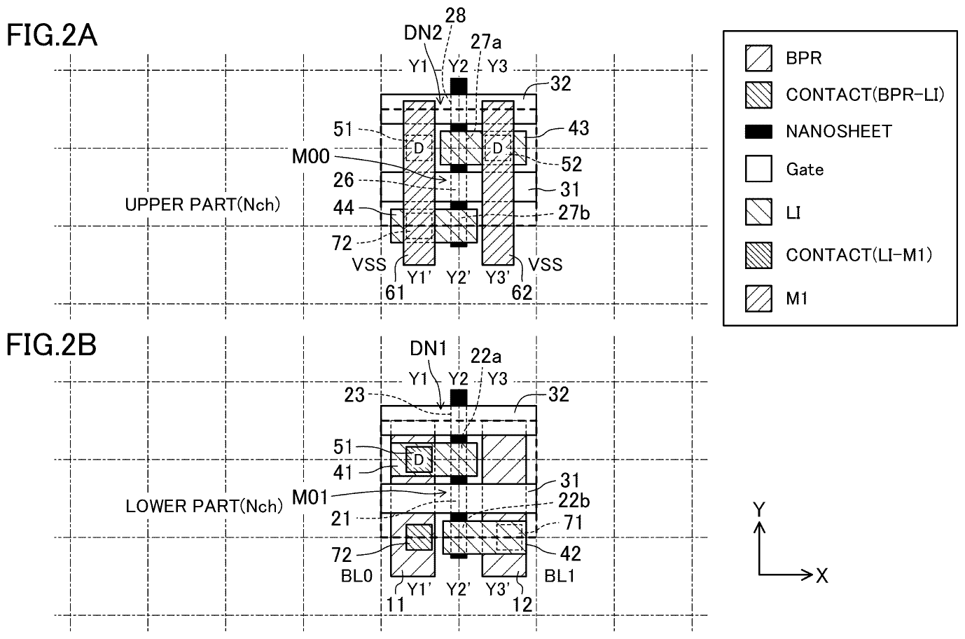

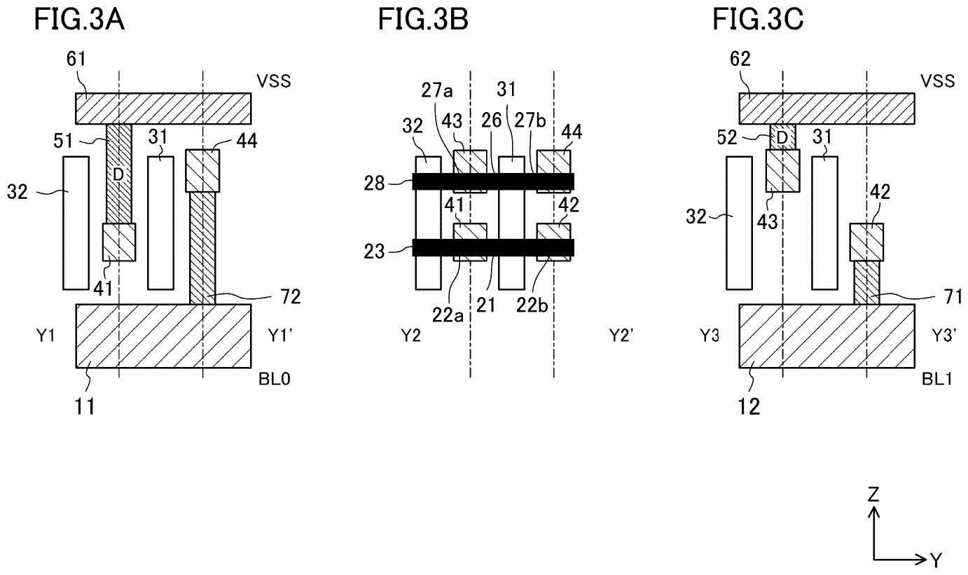

FIGS. 2A-2B and FIGS. 3A-3C are views showing an example of the layout structure of a mask ROM according to the first embodiment, in which FIGS. 2A-2B are plan views of a memory cell and FIGS. 3A-3C are cross-sectional views of the memory cell taken vertically in planar view. Specifically, FIG. 2A shows an upper part, i.e., a portion including a three-dimensional transistor (an n-type nanosheet FET in this example) formed at a position away from the substrate, and FIG. 2B shows a lower part, i.e., a portion including a three-dimensional transistor (an n-type nanosheet FET in this example) formed at a position closer to the substrate. FIG. 3A shows a cross section taken along line Y1-Y1′, FIG. 3B shows a cross section taken along line Y2-Y2′, and FIG. 3C shows a cross section taken along line Y3-Y3′.

In the following description, in the plan views such as FIGS. 2A-2B, the horizontal direction in the figure is called an X direction (corresponding to the first direction), the vertical direction in the figure is called a Y direction (corresponding to the second direction), and the direction perpendicular to the substrate plane is called a Z direction (corresponding to the depth direction). Note that the X direction is the direction in which gate interconnects and word lines extend, and the Y direction is the direction in which nanosheets and bit lines extend. Also, the dot-dash lines running horizontally and vertically in the plan views such as FIGS. 2A-2B and the dot-dash lines running vertically in the cross-sectional views such as FIGS. 3A-3C represent grid lines used for placement of components during designing. The grid lines are arranged at an equal spacing in the X direction and also arranged at an equal spacing in the Y direction. The grid spacings in the X direction and the Y direction may be the same or different from each other. Also, different grid spacings may be used among layers. It is not necessarily required to place the components on grid lines. However, from the standpoint of preventing or reducing manufacturing variations, it is preferable to place the components on grid lines.

Also, in the drawings, each contact determining the memory value of a memory cell is marked with the letter “D”.

FIGS. 2A-2B and 3A-3C correspond to a layout of two bits' worth of memory cells arranged in the horizontal direction in the memory cell array 3 in FIG. 1. A transistor connected to the bit line BL0 is formed in the upper part shown in FIG. 2A, and a transistor connected to the bit line BL1 is formed in the lower part shown in FIG. 2B. That is, the transistors shown in FIGS. 2A and 2B respectively correspond to the n-type transistors M00 and M01 in the circuit diagram of FIG. 1. The dashed lines in the figures indicate the boundaries of the memory cell.

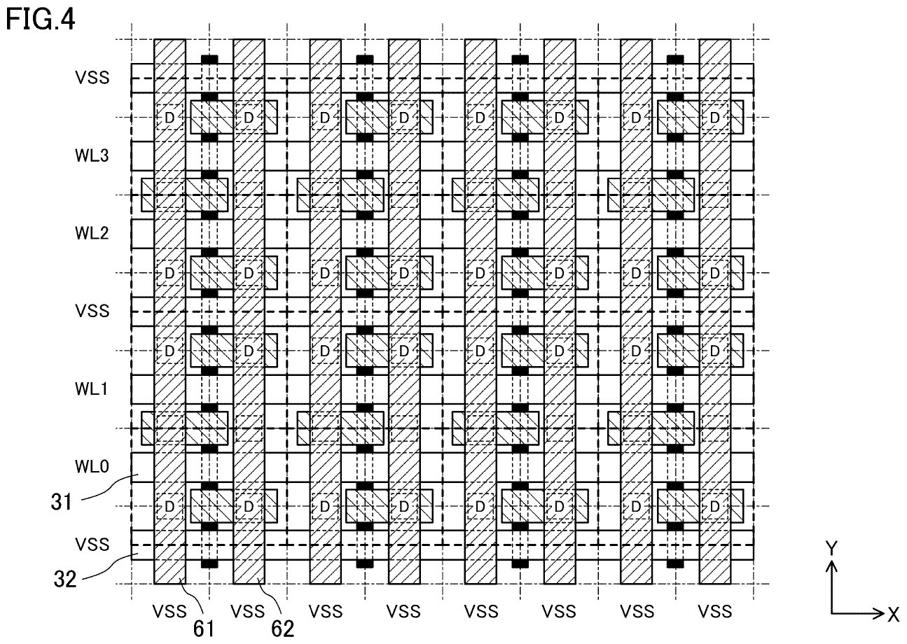

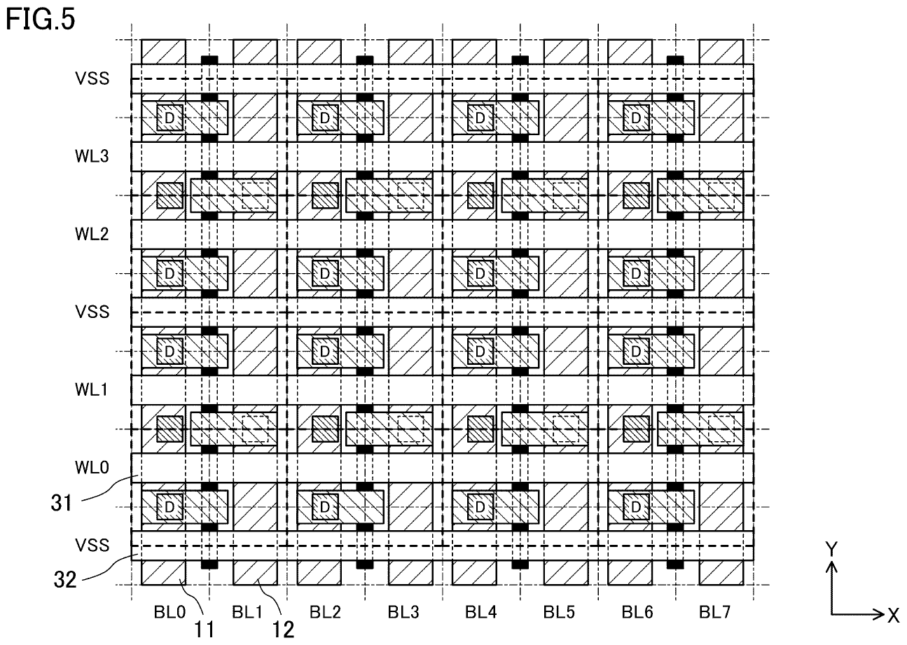

FIGS. 4 and 5 are views showing a layout structure of the memory cell array using the memory cell of FIGS. 2A-2B and 3A-3C, in which FIG. 4 shows the upper part and FIG. 5 shows the lower part.

As shown in FIG. 2B, interconnects 11 and 12 extending in the Y direction are laid in a buried interconnect (BI) layer. The buried interconnect 11 corresponds to the bit line BL0 and the buried interconnect 12 corresponds to the bit line BL1.

As shown in FIG. 2A, power supply lines 61 and 62 extending in the Y direction are formed in an M1 interconnect layer. The M1 power supply lines 61 and 62 both supply the power supply voltage VSS.

A nanosheet 21 extending in the Y direction is formed in the lower part of the memory cell, and a nanosheet 26 extending in the Y direction is formed in the upper part of the memory cell. The nanosheets 21 and 26 overlap each other in planar view. Pads 22a and 22b doped with an n-type semiconductor are formed on both ends of the nanosheet 21, and pads 27a and 27b doped with an n-type semiconductor are formed on both ends of the nanosheet 26. The nanosheet 21 constitutes the channel portion of the n-type transistor M01, and the pads 22a and 22b each constitute a terminal that is to be the source or drain of the n-type transistor M01. The nanosheet 26 constitutes the channel portion of the n-type transistor M00, and the pads 27a and 27b each constitute a terminal that is to be the source or drain of the n-type transistor M00. The n-type transistor M01 is formed above the buried interconnect layer in the Z direction, and the n-type transistor M00 is formed above the n-type transistor M01 in the Z direction.

A gate interconnect 31 extends in the X direction and also extends in the Z direction over the lower and upper parts of the memory cell. The gate interconnect 31 is to be the gates of the n-type transistors M00 and M01. That is, the n-type transistor M01 is constituted by the nanosheet 21, the gate interconnect 31, and the pads 22a and 22b, and the n-type transistor M00 is constituted by the nanosheet 26, the gate interconnect 31, and the pads 27a and 27b. The gate interconnect 31 is connected to the word line WL0 as will be described later.

A dummy gate interconnect 32 is formed along the upper end of the memory cell in the figure. The dummy gate interconnect 32, like the gate interconnect 31, extends in the X and Z directions. A nanosheet 23 is formed to extend from the pad 22a upward in the figure, and a nanosheet 28 is formed to extend from the pad 27a upward in the figure. N-type transistors DN1 and DN2 are respectively formed by the nanosheet 23 and the dummy gate interconnect 32 and by the nanosheet 28 and the dummy gate interconnect 32. Note however that, since the dummy gate interconnect 32 is connected to VSS (not shown), the n-type transistors DN1 and DN2 are in the off state, causing no influence on the logical operation of the circuit, and therefore are not illustrated in the circuit diagram of FIG. 1.

Local interconnects 41 and 42 extending in the X direction are formed in the lower part of the memory cell. The local interconnect 41 is connected to the pad 22a and extends from the pad 22a leftward in the figure. The local interconnect 42 is connected to the pad 22b and extends from the pad 22b rightward in the figure. Local interconnects 43 and 44 extending in the X direction are formed in the upper part of the memory cell. The local interconnect 43 is connected to the pad 27a and extends from the pad 27a rightward in the figure. The local interconnect 44 is connected to the pad 27b and extends from the pad 27b leftward in the figure.

The local interconnect 42 is connected to the buried interconnect 12 through a contact 71, and the local interconnect 44 is connected to the buried interconnect 11 through a contact 72.

Each of contacts 51 and 52 determines the memory value of the memory cell by its presence or absence. The contact 51, when formed, connects the local interconnect 41 and the M1 power supply line 61. The contact 52, when formed, connects the local interconnect 43 and the M1 power supply line 62.

FIGS. 4 and 5 show a configuration in which memory cells identical to the memory cell of FIGS. 2A-2B are arranged in an array of four in the X direction and four in the Y direction. The memory cells are inverted in the Y direction every other row of memory cells. The gate interconnects 31, shown in the memory cell of FIGS. 2A-2B, are arranged in line in the X direction, forming the word lines WL0 to WL3. Also, the dummy gate interconnects 32 are supplied with VSS. The buried interconnects 11 and 12, shown in the memory cell of FIGS. 2A-2B, are each arranged in line in the Y direction, forming the bit lines BL0 to BL7. Between the word lines WL0 and WL1, drains are shared by adjacent transistors, and between the word lines WL2 and WL3, drains are shared by adjacent transistors.

As described above, according to this embodiment, the ROM cell includes: the transistor M00 provided between the buried interconnect 11 that is to be a bit line and the M1 power supply line 62 that supplies VSS; and the transistor M01 provided between the buried interconnect 12 that is to be a bit line and the M1 power supply line 61 that supplies VSS. The transistor M00 is formed above the transistor M01, and the channel portions of the transistors M00 and M01 overlap each other in planar view. In this ROM cell, first data is stored depending on the presence or absence of connection between the local interconnect 43 connected to the source of the transistor M00 and the M1 power supply line 62. Also, second data is stored depending on the presence or absence of connection between the local interconnect 41 connected to the source of the transistor M01 and the M1 power supply line 61. In this way, a small-area layout structure can be implemented for the mask ROM.

The buried interconnect layer is formed to be buried in the substrate or a shallow trench isolation (STI). Therefore, the resistance value of the buried interconnects can be reduced by increasing the length (thickness) thereof in the depth direction. In this embodiment, since the bit lines are formed in the buried interconnect layer, the resistance value of the bit lines can be reduced by increasing the thickness thereof in the depth direction. It is therefore possible to prevent decrease in the operating speed of the mask ROM without increasing the area.

In addition, both the upper transistor and the lower transistor are n-type transistors and made to form separate memory cells. Also, the drains of transistors of adjacent memory cells in the Y direction are shared. It is therefore possible to achieve reduction in the area of the semiconductor memory device.

Moreover, as is found from the layout of FIG. 4, by providing the dummy gate interconnects 32 in the memory cells, transistors can be formed consecutively in the Y direction. It is therefore possible to prevent or reduce manufacturing variations of transistors.

### (Another Example of Layout Structure)

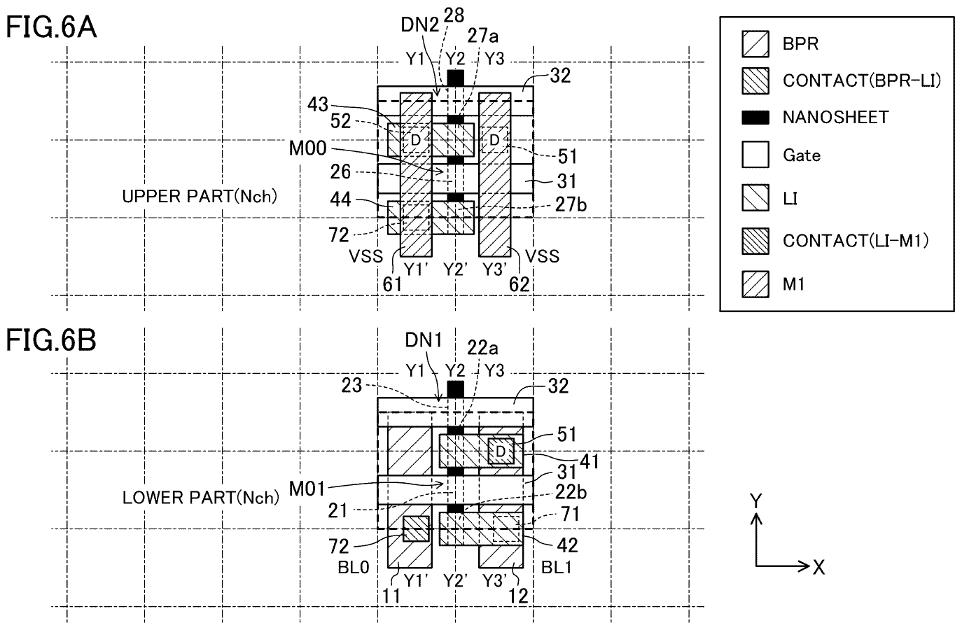

FIGS. 6A-6B are plan views showing another example of the layout structure of the memory cell according to this embodiment, in which FIG. 6A shows the upper part and FIG. 6B shows the lower part. The layout structure of FIGS. 6A-6B is basically the same as that of FIGS. 2A-2B, except for the followings.

In the layout structure of FIGS. 6A-6B, the local interconnects connected to the source and drain of each transistor extend from the transistor in the same direction. In the lower transistor, both the local interconnects 41 and 42 extend rightward in the figure, and the memory value is set depending on the presence or absence of the contact 51 between the local interconnect 41 and the M1 power supply line 62. In the upper transistor, both the local interconnects 43 and 44 extend leftward in the figure, and the memory value is set depending on the presence or absence of the contact 52 between the local interconnect 43 and the M1 power supply line 61.

Note that, in the layout structures described above, it is not necessarily required to provide the dummy gate interconnect 32, nor form the n-type transistors DN1 and DN2.

In the layout structures described above, the memory value of each memory cell is determined depending on the presence or absence of the contact between the local interconnect connected to the source of the transistor and the ground power supply line formed in the M1 interconnect layer. In place of this, the layout structure may be made to determine the memory value of the memory cell depending on the presence or absence of the contact between the local interconnect connected to the drain of the transistor and the bit line formed in the buried interconnect layer. Note however that, by using a contact between a local interconnect and an M1 interconnect located in the upper part, it is possible to start the manufacturing process for changing the memory value of a memory cell from a later process step, and this can shorten the manufacturing time period.

### Second Embodiment

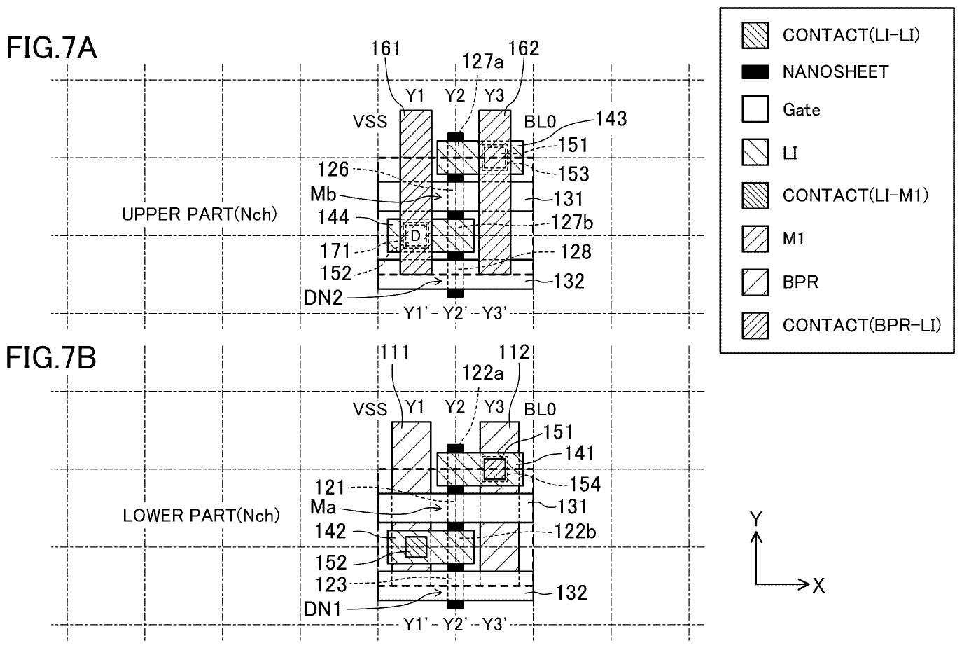

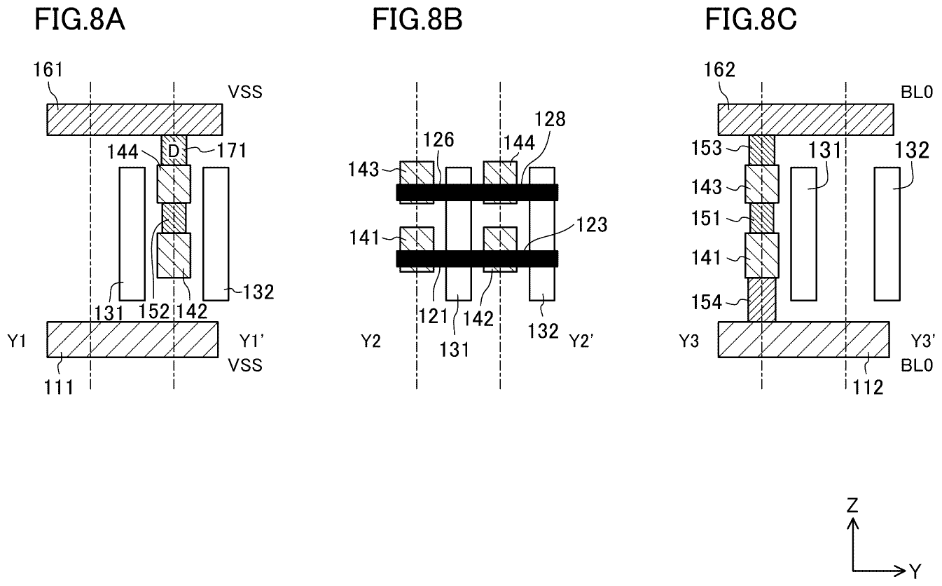

FIGS. 7A-7B and FIGS. 8A-8C are views showing an example of the layout structure of a mask ROM according to the second embodiment, in which FIGS. 7A-7B are plan views of a memory cell and FIGS. 8A-8C are cross-sectional views of the memory cell taken vertically in planar view. Specifically, FIG. 7A shows an upper part and FIG. 7B shows a lower part. FIG. 8A shows a cross section taken along line Y1-Y1′, FIG. 8B shows a cross section taken along line Y2-Y2′, and FIG. 8C shows a cross section taken along line Y3-Y3′.

FIGS. 7A-7B and 8A-8C correspond to a layout of one bit's worth of memory cell in the memory cell array 3 of FIG. 1. The one-bit memory cell is constituted by an n-type transistor formed in the upper part shown in FIG. 7A and an n-type transistor formed in the lower part shown in FIG. 7B. That is, the transistors shown in FIGS. 7A and 7B correspond to the n-type transistor M00 in the circuit diagram of FIG. 1. The dashed lines in the figures indicate the boundaries of the memory cell.

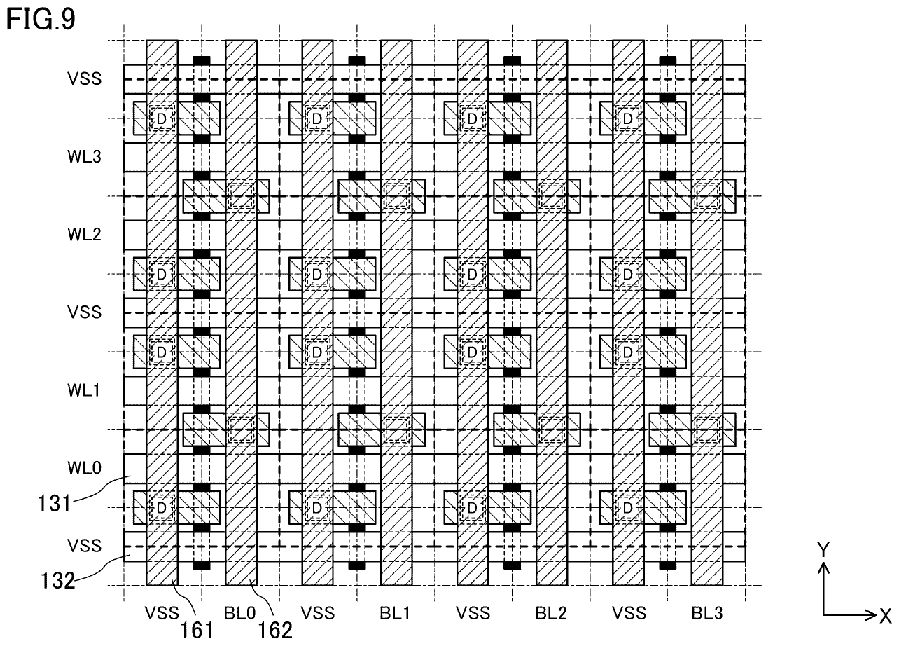

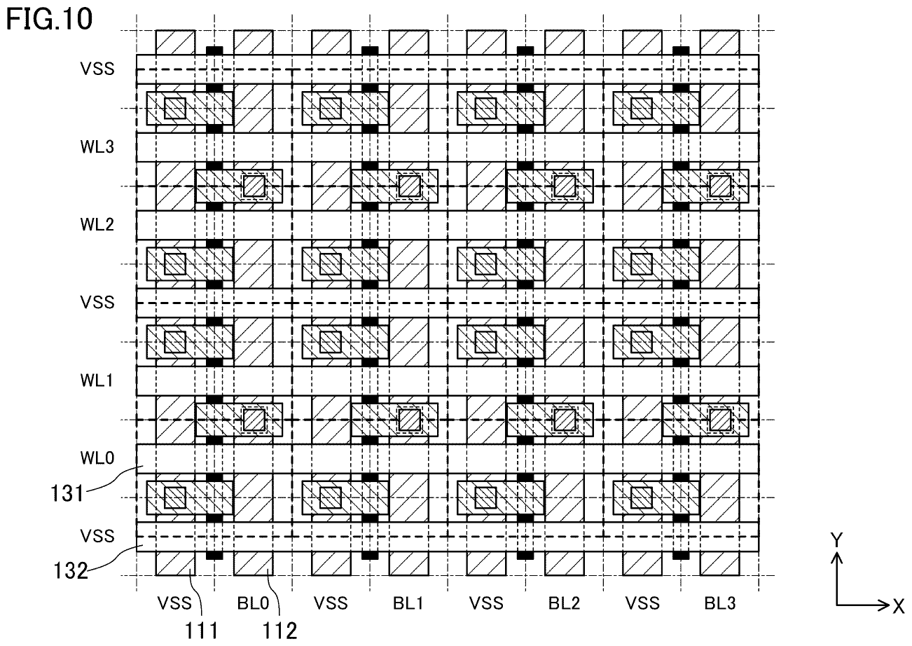

FIGS. 9 and 10 are views showing a layout structure of the memory cell array using the memory cell of FIGS. 7A-7B and 8A-8C, in which FIG. 9 shows the upper part and FIG. 10 shows the lower part.

As shown in FIG. 7A, interconnects 161 and 162 extending in the Y direction are formed in an M1 interconnect layer. The M1 interconnect 161 supplies the power supply voltage VSS, and the M1 interconnect 162 corresponds to the bit line BL0.

As shown in FIG. 7B, interconnects 111 and 112 extending in the Y direction are formed in a buried interconnect layer. The buried interconnect 111 supplies the power supply voltage VSS, and the buried interconnect 112 corresponds to the bit line BL0.

A nanosheet 121 extending in the Y direction is formed in the lower part of the memory cell, and a nanosheet 126 extending in the Y direction is formed in the upper part of the memory cell. The nanosheets 121 and 126 overlap each other in planar view. Pads 122a and 122b doped with an n-type semiconductor are formed on both ends of the nanosheet 121, and pads 127a and 127b doped with an n-type semiconductor are formed on both ends of the nanosheet 126. The nanosheet 121 constitutes the channel portion of an n-type transistor Ma, and the pads 122a and 122b each constitute a terminal that is to be the source or drain of the n-type transistor Ma. The nanosheet 126 constitutes the channel portion of an n-type transistor Mb, and the pads 127a and 127b each constitute a terminal that is to be the source or drain of the n-type transistor Mb. The n-type transistor Ma is formed above the buried interconnect layer in the Z direction, and the n-type transistor Mb is formed above the n-type transistor Ma in the Z direction.

A gate interconnect 131 extends in the X direction and also extends in the Z direction over the lower and upper parts of the memory cell. The gate interconnect 131 is to be the gates of the n-type transistors Ma and Mb. That is, the n-type transistor Ma is constituted by the nanosheet 121, the gate interconnect 131, and the pads 122a and 122b, and the n-type transistor Mb is constituted by the nanosheet 126, the gate interconnect 131, and the pads 127a and 127b. The gate interconnect 131 is connected to the word line WL0 as will be described later.

A dummy gate interconnect 132 is formed along the lower end of the memory cell in the figure. The dummy gate interconnect 132, like the gate interconnect 131, extends in the X and Z directions. A nanosheet 123 is formed to extend from the pad 122b downward in the figure, and a nanosheet 128 is formed to extend from the pad 127b downward in the figure. N-type transistors DN1 and DN2 are respectively formed by the nanosheet 123 and the dummy gate interconnect 132 and by the nanosheet 128 and the dummy gate interconnect 132. Note however that, since the dummy gate interconnect 132 is connected to VSS (not shown), the n-type transistors DN1 and DN2 are in the off state, causing no influence on the logical operation of the circuit, and therefore are not illustrated in the circuit diagram of FIG. 1.

Local interconnects 141 and 142 extending in the X direction are formed in the lower part of the memory cell. The local interconnect 141 is connected to the pad 122a and extends from the pad 122a rightward in the figure. The local interconnect 142 is connected to the pad 122b and extends from the pad 122b leftward in the figure. Local interconnects 143 and 144 extending in the X direction are formed in the upper part of the memory cell. The local interconnect 143 is connected to the pad 127a and extends from the pad 127a rightward in the figure. The local interconnect 144 is connected to the pad 127b and extends from the pad 127b leftward in the figure.

The local interconnect 141 is connected to the local interconnect 143 through a contact 151, and the local interconnect 142 is connected to the local interconnect 144 through a contact 152. The local interconnect 143 is connected to the M1 interconnect 162 through a contact 153, and the local interconnect 141 is connected to the buried interconnect 112 through a contact 154.

A contact 171 determines the memory value of the memory cell by its presence or absence. The contact 171, when formed, connects the local interconnect 144 and the M1 interconnect 161.

FIGS. 9 and 10 show a configuration in which memory cells identical to the memory cell of FIGS. 7A-7B are arranged in an array of four in the X direction and four in the Y direction. The memory cells are inverted in the Y direction every other row of memory cells. The gate interconnects 131, shown in the memory cell of FIGS. 7A-7B, are arranged in line in the X direction, forming the word lines WL0 to WL3. Also, the dummy gate interconnects 132 are supplied with VSS. The M1 interconnects 161 and 162, shown in the memory cell of FIGS. 7A-7B, are each arranged in line in the Y direction, respectively forming the lines supplying the power supply voltage VSS and the bit lines BL0 to BL3. The buried interconnects 111 and 112, shown in the memory cell of FIGS. 7A-7B, are each arranged in line in the Y direction, respectively forming the lines supplying the power supply voltage VSS and the bit lines BL0 to BL3. Between the word lines WL0 and WL1, drains are shared by adjacent transistors, and between the word lines WL2 and WL3, drains are shared by adjacent transistors.

As described above, according to this embodiment, the ROM cell includes the transistors Ma and Mb provided between the buried interconnect 112 and the M1 interconnect 162 that are to be the bit lines and the M1 interconnect 161 that supplies VSS. The transistor Mb is formed above the transistor Ma and the channel portions of the transistors Ma and Mb overlap each other in planar view. The local interconnect 142 connected to the source of the transistor Ma and the local interconnect 144 connected to the source of the transistor Mb are mutually connected. The local interconnect 141 connected to the drain of the transistor Ma and the local interconnect 143 connected to the drain of the transistor Mb are mutually connected. In this ROM cell, data is stored depending on the presence or absence of connection between the local interconnect 144 and the M1 interconnect 161. In this way, a small-area layout structure can be implemented for the mask ROM.

The buried interconnect layer is formed to be buried in the substrate or a shallow trench isolation (STI). Therefore, the resistance value of the buried interconnects can be reduced by increasing the length (thickness) thereof in the depth direction. In this embodiment, since bit lines are formed in the buried interconnect layer, the resistance value of the bit lines can be reduced by increasing the thickness thereof in the depth direction. It is therefore possible to prevent decrease in the operating speed of the mask ROM without increasing the area.

In this embodiment, since a one-bit memory cell is constituted by two transistors formed in the upper part and the lower part, the drive capability is great, permitting high-speed operation, compared with the first embodiment. Also, when the transistor characteristics vary between the upper part and the lower part, the characteristics vary bit line by bit line in the first embodiment. In this embodiment, however, there is no influence of such variations. Moreover, since the memory value of the memory cell is set by the contact located at a further upper position compared with the first embodiment, the manufacturing time period for changing the memory value of a memory cell can be shortened. On the other hand, in the first embodiment, the area of the memory cell array can be reduced compared with this embodiment.

Also, in this embodiment, bit lines are provided not only in the buried interconnect layer but also in the M1 interconnect layer. This can further reduce the resistance value of the bit lines. Note however that the bit lines in the M1 interconnect layer may be omitted.

Moreover, in the buried interconnect layer, since lines supplying the power supply voltage VSS are placed between the bit lines, crosstalk noise between the bit lines can be avoided, whereby the stability of operation can be achieved. Similarly, in the M1 interconnect layer, since lines supplying the power supply voltage VSS are placed between the bit lines, crosstalk noise between the bit lines can be avoided, whereby the stability of operation can be achieved.

In this embodiment, as the contact for determining the memory value of a memory cell, a contact between a local interconnect in the upper part and an M1 interconnect supplying VSS is used. In place of this, a contact between a local interconnect in the lower part and a buried interconnect supplying VSS may be used as the contact for determining the memory value of a memory cell. Note however that, by using a contact between a local interconnect in the upper part and an M1 interconnect, it is possible to start the manufacturing process for changing the memory value of a memory cell from a later process step, and this can shorten the manufacturing time period.

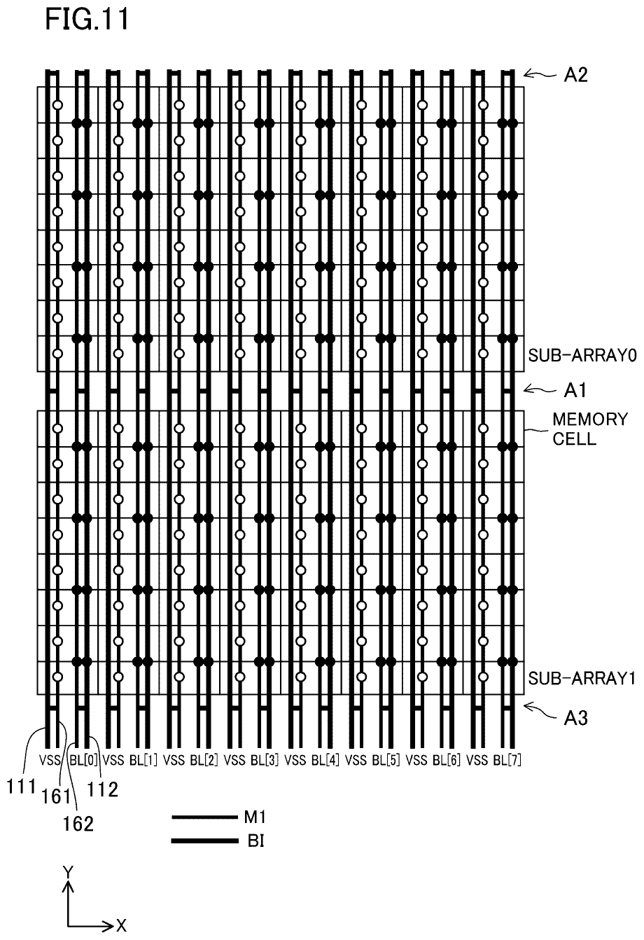

FIG. 11 shows a layout example of a memory array unit of the semiconductor memory device of this embodiment. Note that, although memory cells are diagrammatically illustrated as rectangles in FIG. 11, each memory cell has a structure shown in FIGS. 7A-7B and 8A-8C.

The memory array unit of FIG. 11 includes two sub-arrays 0 and 1, although the number of sub-arrays included in the memory array unit is not limited to this. The sub-arrays 0 and 1 each have (8×8) memory cells, although the number of memory cells included in each sub-array is not limited to this. Also, portions A1, A2, and A3 in which no memory cell is formed are respectively provided between the sub-arrays 0 and 1, on the upper side of the sub-array 0, and on the lower side of the sub-array 1 in the figure.

In the sub-arrays 0 and 1, pairs of bit lines BL formed in the buried interconnect layer and the M1 interconnect layer and pairs of VSS lines formed in the buried interconnect layer and the M1 interconnect layer extend in the Y direction. In FIG. 11, for the memory cell located in the lower-left corner of the sub-array 1 in the figure, the interconnects corresponding to the buried interconnects 111 and 112 and the M1 interconnects 161 and 162 shown in FIGS. 7A-7B and 8A-8C are denoted by the same reference characters. By placing the memory cells adjacent to one another in the Y direction, the buried interconnects, and the M1 interconnects, are mutually connected. In this way, the pairs of bit lines BL formed in the buried interconnect layer and the M1 interconnect layer and the pairs of VSS lines formed in the buried interconnect layer and the M1 interconnect layer are provided.

In each memory cell, a pair of bit lines BL formed in the buried interconnect layer and the M1 interconnect layer are connected to local interconnects, which are connected to the drains of the corresponding transistors, through contacts. In FIG. 11, contacts connecting the pairs of bit lines BL and the local interconnects are indicated by black circles on the boundaries between memory cells.

In each memory cell, a VSS line formed in the M1 interconnect layer is connected to, or not connected to, local interconnects, which are connected to the sources of the corresponding transistors, according to the memory value. In FIG. 11, the positions where contacts for connecting the VSS lines formed in the M1 interconnect layer and the local interconnects are placed are indicated by white circles. The VSS lines formed in the buried interconnect layer are not connected to the transistors.

In the portion A1 between the sub-arrays 0 and 1, the portion A2 on the upper side of the sub-array 0, and the portion A3 on the lower side of the sub-array 1 in the figure, each pair of VSS lines, i.e., the VSS line formed in the M1 interconnect layer and the VSS line formed in the buried interconnect layer, are mutually connected. This strengthens power supply.

Note that, in FIG. 11, for all the memory cells, both the bit lines formed in the M1 interconnect layer and the bit lines formed in the buried interconnect layer are connected to the local interconnects that are connected to the drains of the transistors. However, it is not necessarily required to connect both the bit line formed in the M1 interconnect layer and the bit line formed in the buried interconnect layer to the corresponding local interconnects, but is just required to connect at least one bit line to the corresponding local interconnect for each memory cell.

For example, for all the memory cells, only the bit lines formed in the M1 interconnect layer may be connected to the corresponding local interconnects. Conversely, for all the memory cells, only the bit lines formed in the buried interconnect layer may be connected to the corresponding local interconnects. Alternatively, while the bit lines formed in the M1 interconnect layer may be connected to the corresponding local interconnects for all the memory cells, bit lines formed in the buried interconnect layer may be connected to the corresponding local interconnects for some memory cells. Conversely, while the bit lines formed in the buried interconnect layer may be connected to the corresponding local interconnects for all the memory cells, bit lines formed in the M1 interconnect layer may be connected to the corresponding local interconnects for some memory cells.

Alternatively, while bit lines formed in the M1 interconnect layer may be connected to the corresponding local interconnects for some memory cells, bit lines formed in the buried interconnect layer may be connected to the corresponding local interconnects for the remaining memory cells. In this case, the memory cells in which the bit lines formed in the M1 interconnect layer are connected to the corresponding local interconnects and the memory cells in which the bit lines formed in the buried interconnect layer are connected to the corresponding local interconnects may be placed alternately in the X direction and the Y direction.

By omitting part of the connection between the local interconnects and the bit line pairs in the memory array unit as in the configurations described above, the load capacitance of the bit lines can be reduced.

### (Another Example of Layout Structure)

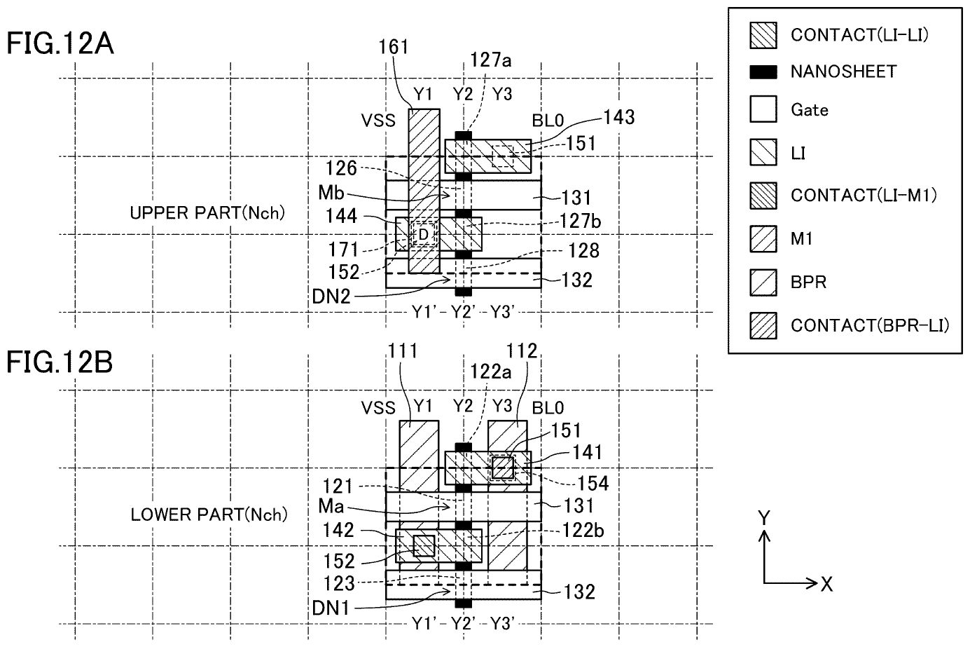

FIGS. 12A-12B are plan views showing another example of the layout structure of the memory cell according to this embodiment, in which FIG. 12A shows the upper part and FIG. 12B shows the lower part. The layout structure of FIGS. 12A-12B is basically the same as that of FIGS. 7A-7B, except for the followings.

In the layout structure of FIGS. 12A-12B, the M1 interconnect 162 corresponding to the bit line BL0 is omitted. That is, only the buried interconnect 112 corresponds to the bit line BL0. With this, the resistance value of the bit lines becomes sufficiently low, and the load capacitance of the bit lines can be reduced if only no operational problem occurs.

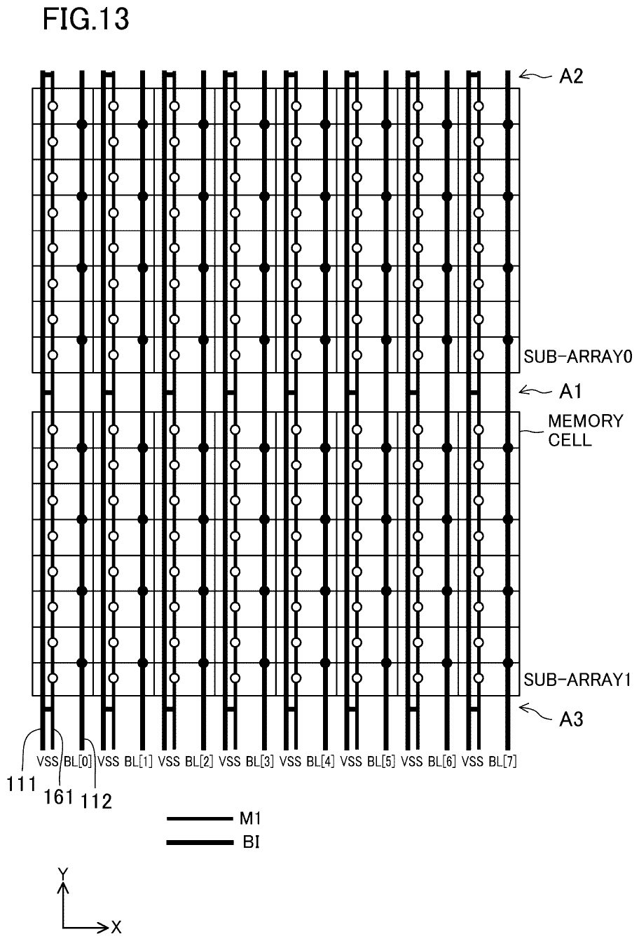

FIG. 13 shows a layout example of a memory array unit using the memory cell of FIGS. 12A-12B. In comparison with FIG. 11, the M1 interconnects corresponding to the bit lines BL are omitted. The other configuration is similar to that of FIG. 11, and therefore detailed description thereof is omitted here.

In the sub-arrays 0 and 1, bit lines BL formed in the buried interconnect layer and pairs of VSS lines formed in the buried interconnect layer and the M1 interconnect layer extend in the Y direction. In each memory cell, a bit line BL formed in the buried interconnect layer is connected to local interconnects, which are connected to the drains of the corresponding transistors, through contacts (black circle). Also, in each memory cell, a VSS line formed in the M1 interconnect layer is connected to, or not connected to, local interconnects, which are connected to the sources of the corresponding transistors, according to the memory value (white circle).

### Third Embodiment

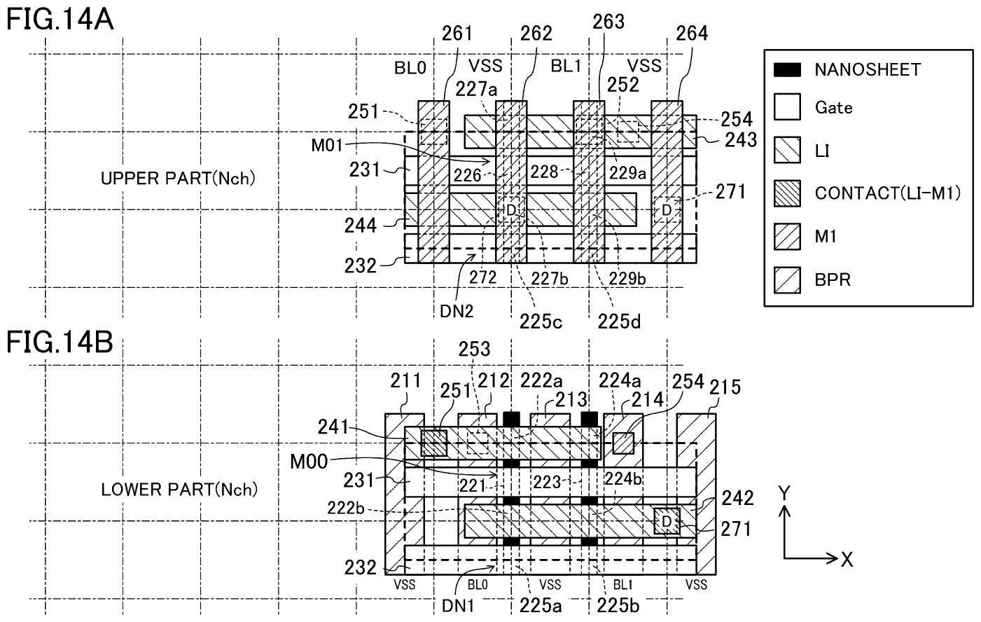

FIGS. 14A-14B are views showing an example of the layout structure of a mask ROM according to the third embodiment, and show plan views of a memory cell, in which FIG. 14A shows an upper part and FIG. 14B shows a lower part.

FIGS. 14A-14B correspond to a layout of two bits' worth of memory cells arranged in the horizontal direction in the memory cell array 3 of FIG. 1. A transistor connected to the bit line BL0 is formed in the lower part shown in FIG. 14B, and a transistor connected to the bit line BL1 is formed in the upper part shown in FIG. 14A. That is, the transistors shown in FIGS. 14A and 14B respectively correspond to the n-type transistors M01 and M00 in the circuit diagram of FIG. 1. In this embodiment, each of the n-type transistors M01 and M00 is constituted by two parallel-connected transistors arranged in the X direction. The dashed lines in the figures indicate the boundaries of the memory cell.

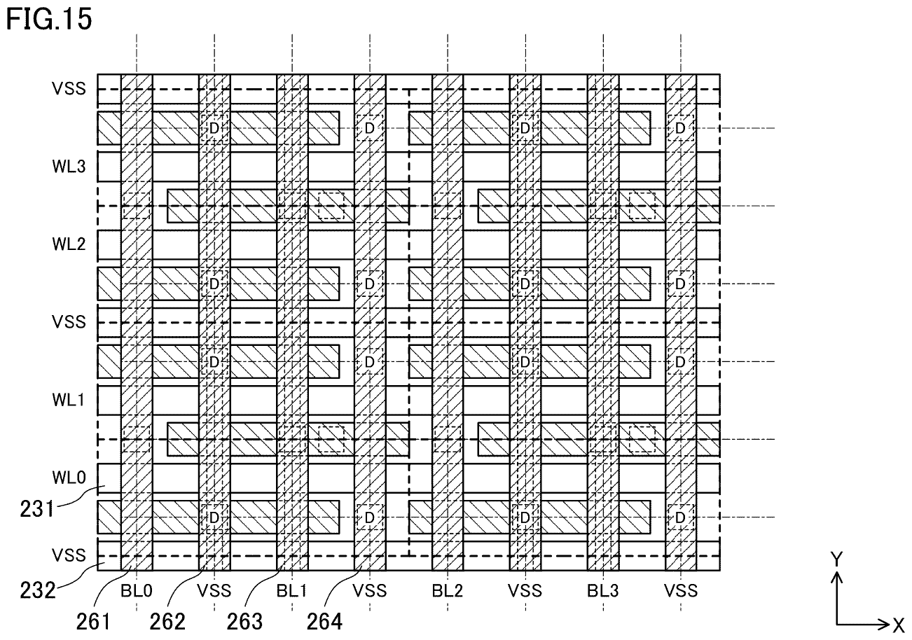

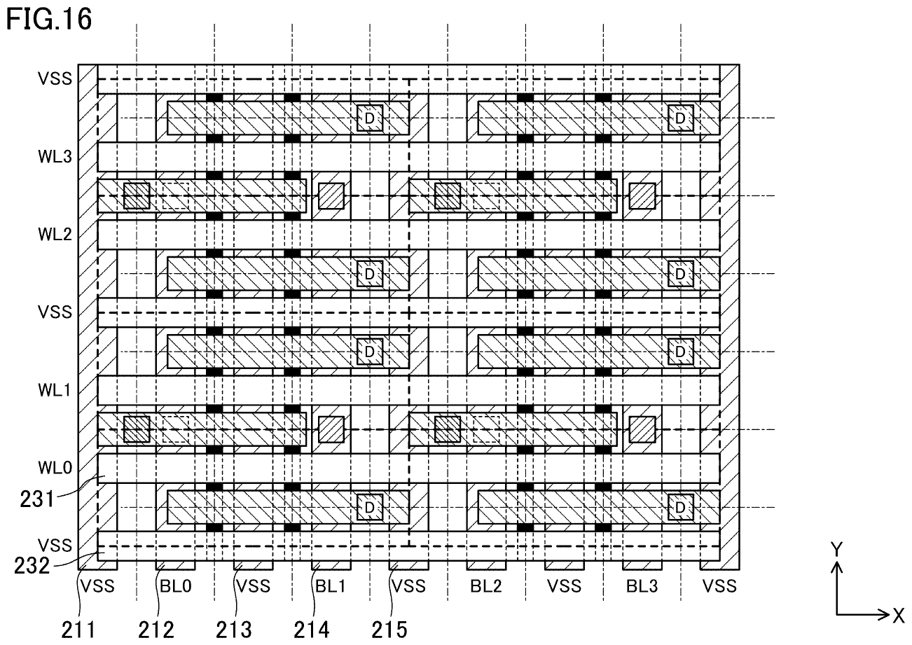

FIGS. 15 and 16 are views showing a layout structure of a memory cell array using the memory cell of FIGS. 14A-14B, in which FIG. 15 shows the upper part and FIG. 16 shows the lower part.

As shown in FIG. 14A, interconnects 261, 262, 263, and 264 extending in the Y direction are formed in an M1 interconnect layer. The M1 interconnect 261 corresponds to the bit line BL0, the interconnects 262 and 264 supply the power supply voltage VSS, and the M1 interconnect 263 corresponds to the bit line BL1.

As shown in FIG. 14B, interconnects 211, 212, 213, 214, and 215 extending in the Y direction are formed in a buried interconnect layer. The buried interconnect 212 corresponds to the bit line BL0, the buried interconnect 214 corresponds to the bit line BL1, and the buried interconnects 211, 213, and 215 supply the power supply voltage VSS.

Nanosheets 221 and 223 extending in the Y direction are formed in the lower part of the memory cell, and nanosheets 226 and 228 extending in the Y direction are formed in the upper part of the memory cell. The nanosheets 221 and 226 overlap each other in planar view, and the nanosheets 223 and 228 overlap each other in planar view. Pads 222a and 222b doped with an n-type semiconductor are formed on both ends of the nanosheet 221, and pads 224a and 224b doped with an n-type semiconductor are formed on both ends of the nanosheet 223. Pads 227a and 227b doped with an n-type semiconductor are formed on both ends of the nanosheet 226, and pads 229a and 229b doped with an n-type semiconductor are formed on both ends of the nanosheet 228. The nanosheets 221 and 223 constitute channel portions of the n-type transistor M00, and the pads 222a, 222b, 224a, and 224b each constitute a terminal that is to be the source or drain of the n-type transistor M00. The nanosheets 226 and 228 constitute channel portions of the n-type transistor M01, and the pads 227a, 227b, 229a, and 229b each constitute a terminal that is to be the source or drain of the n-type transistor M01. The n-type transistor M00 is formed above the buried interconnect layer in the Z direction, and the n-type transistor M01 is formed above the n-type transistor M00 in the Z direction.

A gate interconnect 231 extends in the X direction and also extends in the Z direction over the lower and upper parts of the memory cell. The gate interconnect 231 is to be the gates of the n-type transistors M00 and M01. That is, the n-type transistor M00 is constituted by the nanosheets 221 and 223, the gate interconnect 231, and the pads 222a, 222b, 224a, and 224b, and the n-type transistor M01 is constituted by the nanosheets 226 and 228, the gate interconnect 231, and the pads 227a, 227b, 229a, and 229b. The gate interconnect 231 is connected to the word line WL0 as will be described later.

A dummy gate interconnect 232 is formed along the lower end of the memory cell in the figure. The dummy gate interconnect 232, like the gate interconnect 231, extends in the X and Z directions. A nanosheet 225a is formed to extend from the pad 222b downward in the figure, and a nanosheet 225b is formed to extend from the pad 224b downward in the figure. A nanosheet 225c is formed to extend from the pad 227b downward in the figure, and a nanosheet 225d is formed to extend from the pad 229b downward in the figure. N-type transistors DN1 and DN2 are respectively formed by the nanosheets 225a and 225b and the dummy gate interconnect 232 and by the nanosheets 225c and 225d and the dummy gate interconnect 232. Note however that, since the dummy gate interconnect 232 is connected to VSS (not shown), the n-type transistors DN1 and DN2 are in the off state, causing no influence on the logical operation of the circuit

Local interconnects 241 and 242 extending in the X direction are formed in the lower part of the memory cell. The local interconnect 241 is connected to the pads 222a and 224a and extends from the pad 222a leftward in the figure. The local interconnect 242 is connected to the pads 222b and 224b and extends from the pad 224b rightward in the figure. Local interconnects 243 and 244 extending in the X direction are formed in the upper part of the memory cell. The local interconnect 243 is connected to the pads 227a and 229a and extends from the pad 229a rightward in the figure. The local interconnect 244 is connected to the pads 227b and 229b and extends from the pad 227b leftward in the figure.

The local interconnect 241 is connected to the M1 interconnect 261 through a contact 251, and the local interconnect 243 is connected to the M1 interconnect 263 through a contact 252. Also, the local interconnect 241 is connected to the buried interconnect 212 through a contact 253, and the local interconnect 243 is connected to the buried interconnect 214 through a contact 254.

Contacts 271 and 272 each determine the memory value of the memory cell by their presence or absence. The contact 271, when formed, connects the local interconnect 242 and the M1 interconnect 264. The contact 272, when formed, connects the local interconnect 244 and the M1 interconnect 262.

FIGS. 15 and 16 show a configuration in which memory cells identical to the memory cell of FIGS. 14A-14B are arranged in an array of two in the X direction and four in the Y direction. The memory cells are inverted in the Y direction every other row of memory cells. The gate interconnects 231, shown in the memory cell of FIGS. 14A-14B, are arranged in line in the X direction, forming the word lines WL0 to WL3. Also, the dummy gate interconnects 232 are supplied with VSS. The M1 interconnects 261 to 264, shown in the memory cell of FIGS. 14A-14B, are each arranged in line in the Y direction, forming the lines supplying the power supply voltage VSS and the bit lines BL0 to BL3. The buried interconnects 211 to 215, shown in the memory cell of FIGS. 14A-14B, are each arranged in line in the Y direction, forming the lines supplying the power supply voltage VSS and the bit lines BL0 to BL3. Between the word lines WL0 and WL1, drains are shared by adjacent transistors, and between the word lines WL2 and WL3, drains are shared by adjacent transistors.

As described above, according to this embodiment, the ROM cell includes: the transistor M00 provided between the buried interconnect 212 and the M1 interconnect 261 that are to be the bit lines and the M1 interconnect 264 that supplies VSS; and the transistor M01 provided between the buried interconnect 214 and the M1 interconnect 263 that are to be the bit lines and the M1 interconnect 262 that supplies VSS. The transistor M01 is formed above the transistor M00, and the channel portions of the transistors M00 and M01 overlap each other. The transistors M00 and M01 each include two transistors that are arranged in the X direction and share the source and the drain. In this ROM cell, first data is stored depending on the presence or absence of connection between the local interconnect 242 connected to the source shared by the two transistors of the transistor M00 and the M1 interconnect 264. Also, second data is stored depending on the presence or absence of connection between the local interconnect 244 connected to the source shared by the two transistors of the transistor M01 and the M1 interconnect 262. In this way, a small-area layout structure can be implemented for the mask ROM.

The buried interconnect layer is formed to be buried in the substrate or a shallow trench isolation (STI). Therefore, the resistance value of the buried interconnects can be reduced by increasing the length (thickness) thereof in the depth direction. In this embodiment, since bit lines are formed in the buried interconnect layer, the resistance value of the bit lines can be reduced by increasing the thickness thereof in the depth direction. It is therefore possible to prevent decrease in the operating speed of the mask ROM without increasing the area.

In addition, by providing bit lines not only in the buried interconnect layer but also in the M1 interconnect layer, the resistance value of the bit lines can be further reduced. Note however that the bit lines in the M1 interconnect layer may be omitted.

Also, in the buried interconnect layer, since lines supplying the power supply voltage VSS are placed between the bit lines, crosstalk noise between bit lines can be avoided, whereby the stability of operation can be achieved. Similarly, in the M1 interconnect layer, since lines supplying the power supply voltage VSS are placed between the bit lines, crosstalk noise between bit lines can be avoided, whereby the stability of operation can be achieved.

While each of the transistors constituting the memory cell includes two transistors connected in parallel in the above example, it may include three or more transistors connected in parallel.

In this embodiment, as the contact for determining the memory value of a memory cell, a contact between a local interconnect and an M1 interconnect supplying VSS is used. In place of this, a contact between a local interconnect and a buried interconnect supplying VSS may be used as the contact for determining the memory value of a memory cell. Note however that, by using a contact between a local interconnect and an M1 interconnect, it is possible to start the manufacturing process for changing the memory value of a memory cell from a later process step, and this can shorten the manufacturing time period.

### Other Examples

While each transistor includes one nanosheet in the above embodiments, part or all of transistors may each include a plurality of nanosheets. In this case, a plurality of nanosheets may be placed in the X direction in planar view, or a plurality of nanosheets may be placed in the Z direction. Alternatively, a plurality of nanosheets may be placed in both the X direction and the Z direction. Also, the number of nanosheets of each transistor may be different between the upper part and lower part of the cell.

While the cross-sectional shape of the nanosheet is roughly a square in the above embodiments, it is not limited to this. For example, it may be a circle or a rectangle.

While the above embodiments have been described taking the nanosheet FET as an example of the three-dimensional transistors, the present disclosure is not limited to this. For example, the transistor formed in the lower part of each cell may be a fin transistor.

According to the present disclosure, decrease in the operating speed of the mask ROM can be prevented without increase in area. The present disclosure is therefore useful for downsizing, and improvement in the performance, of a semiconductor chip, for example.

1. A semiconductor memory device having a read only memory (ROM) cell, comprising:
a word line extending in a first direction;
first and second bit lines extending in a second direction perpendicular to the first direction, formed in a buried interconnect layer; and
first and second ground power supply lines extending in the second direction, wherein
the ROM cell includes
a first transistor that is a three-dimensional transistor provided between the first bit line and the first ground power supply line, and
a second transistor that is a three-dimensional transistor provided between the second bit line and the second ground power supply line, formed above the first transistor, channel portions of the first and second transistors overlapping each other in planar view,
gates of the first and second transistors are connected to the word line, and
the ROM cell stores first data depending on the presence or absence of connection between a source of the first transistor and the first ground power supply line, or the presence or absence of connection between a drain of the first transistor and the first bit line, and stores second data depending on the presence or absence of connection between a source of the second transistor and the second ground power supply line, or the presence or absence of connection between a drain of the second transistor and the second bit line.

2. The semiconductor memory device of claim 1, wherein
the ROM cell includes
a gate interconnect extending in the first direction and a depth direction, serving as the gates of the first and second transistors, and connected to the word line.

3. The semiconductor memory device of claim 1, wherein
the first and second ground power supply lines are formed in a first interconnect layer located above the buried interconnect layer.

4. The semiconductor memory device of claim 1, wherein
the first transistor includes N (N is an integer equal to or more than 2) transistors arranged in the first direction and sharing the source and the drain, and
the second transistor includes N transistors arranged in the first direction and sharing the source and the drain.

5. A semiconductor memory device having a read only memory (ROM) cell, comprising:
a word line extending in a first direction;
a bit line extending in a second direction perpendicular to the first direction, formed in a buried interconnect layer; and
a ground power supply line extending in the second direction, wherein
the ROM cell includes
a first transistor that is a three-dimensional transistor provided between the bit line and the ground power supply line, and
a second transistor that is a three-dimensional transistor provided between the bit line and the ground power supply line, formed above the first transistor, channel portions of the first and second transistors overlapping each other in planar view,
in the first and second transistors, gates are connected to the word line, sources are connected to each other, and drains are connected to each other, and
the ROM cell stores data depending on the presence or absence of connection between the sources of the first and second transistors and the ground power supply line, or the presence or absence of connection between the drains of the first and second transistors and the bit line.

6. The semiconductor memory device of claim 5, wherein
the ROM cell includes
a gate interconnect extending in the first direction and a depth direction, serving as the gates of the first and second transistors, and connected to the word line.

7. The semiconductor memory device of claim 5, wherein
the ground power supply line is formed in a first interconnect layer located above the buried interconnect layer.
